(19) United States
(12) Patent Application Publication
(10) Pub. No.: US 2016/0093751 A1
(43) Pub. Date: Mar. 31, 2016

(54) SILICON SOLAR CELL WITH FRONT ELECTRODES COVERED BY THIN FILM AND PROCESS FOR MANUFACTURING SAME

(71) Applicant: NANJING SUNPORT POWER CO. LTD., Jiangsu (CN)

(72) Inventors: Zhilei LI, Jiangsu (CN); Zhonglin LU, Jiangsu (CN); Wenting SHENG, Jiangsu (CN); Fengming ZHANG, Jiangsu (CN)

(73) Assignees: NANJING SUNPORT POWER CO. LTD., Nanjing, Jiangsu (CN); NANJING SUNPORT POWER CO. LTD., Nanjing, Jiangsu (CN)

(21) Appl. No.: 14/894,729

(22) PCT Filed: Jul. 30, 2013
(86) PCT No.: PCT/CN2013/080451

§ 371 Date: Nov. 30, 2015

(30) Foreign Application Priority Data
Jun. 4, 2013 (CN) 201310218746.5

(51) Int. Cl. H01L 31/0224; H01L 31/0216

(52) U.S. Cl. CPC H01L 31/02245; H01L 31/02168

(57) ABSTRACT

A silicon solar cell with front electrodes covered by a thin film and a process for manufacturing the same. When an MWT back contact solar cell is manufactured, the front electrodes are covered completely by an antireflection film, namely the front electrodes are directly in contact with the silicon wafer without penetration of the antireflection film, so as to reduce the series resistance, and improve the cell conversion efficiency. Meanwhile, the penetration depth when the front electrode silver paste is printed is also easier to control, so that the process is simplified. The front electrodes covered completely by the antireflection film are not directly in contact with the outside, so as to improve the corrosion resistance and oxidation resistance of the front electrodes.

### FIELD OF THE INVENTION

The present invention relates to a silicon solar cell with front electrodes covered by a thin film and a process for manufacturing the same, and belongs to the field of solar cells.

### BACKGROUND OF THE INVENTION

a process route of film plating before printing is used without exception in the prior art for preparing a solar cell, and in that process route, so strict technical requirements are imposed for front silver paste of the silicon solar cell that not only should it be able to quickly penetrate a thin silicon nitride film, but also it should be able to form a good ohmic contact with a silicon substrate; meanwhile, the capability to penetrate silicon should be strictly controlled to avoid the formation of leakage, and that requirement leads to the fact that the silicon solar cell from silver paste technology has been monopolized by foreign companies such as DuPont and the like. How to break through in the silicon solar cell front silver paste technology becomes the main direction in which efforts are made in the industry; the present invention patent provides another way by which the technical threshold for the silicon solar cell front silver paste is reduced successfully by adjusting the process route, and the present invention is illustrated below by taking a conventional crystalline silicon solar cell as an example. The main process for preparing a conventional solar cell includes the following steps:

Step 1) texturing: subjecting a silicon wafer to corrosion, and texturing.

Step 2) diffusion: carrying out diffusion on the textured silicon wafer, and preparing PN junctions.

Step 3) etching: etching the periphery of the silicon wafer after diffusion to prevent leakage.

Step 4) PSG removing: removing the PSG on the surface of the silicon wafer.

Step 5) plating an antireflection film.

Step 6) preparing back electrodes, and then drying.

Step 7) preparing back surface fields, and then drying.

Step 8) preparing front electrodes, and then drying.

Step 9) sintering.

Step 10) testing and sorting.

After testing and sorting, packing and putting in storage discriminatively according to grade and quality.

In the prior art, when a crystalline silicon solar cell is prepared, the antireflection film is first plated on the silicon wafer and then the front electrodes are printed and sintering is carried out, but that process has the following disadvantages:

1. The front electrode silver paste should have a good penetrability, and can successfully penetrate the thin silicon nitride film.

2. When in contact with the silicon surface, the silver paste is barricaded by the thin silicon nitride film, the contact area is reduced, and thus the series resistance becomes so large that the cell conversion efficiency is affected.

3. When the silver paste forms an ohmic contact with the silicon, it should have a lower penetrability, or otherwise leakage will be caused, which forms a contradiction to the successful penetration of the thin silicon nitride film.

4. The electrodes are exposed on the surface of the thin film, so that they are susceptible to corrosion and oxidation.

### SUMMARY OF THE INVENTION

Object of the invention: The present invention provides a process for manufacturing a silicon solar cell with front electrodes covered by a thin film, wherein the front electrode silver paste has a better penetrability, its contact resistance with the silicon surface is smaller, the cell conversion efficiency is improved, and meanwhile the front electrodes covered by an antireflection film are not so easy to corrode and oxidize.

Technical solution: the technical solution used by the present invention is a process for manufacturing a thin-film covered MWT solar cell, including the following steps:

1) selecting a silicon wafer of a first conductivity type, and forming a cell substrate with via holes by providing the via holes in predetermined positions of the silicon wafer, texturing, diffusing, performing via hole back junction protection and etching;

2) removing PSG on the surface of the cell substrate;

3) filling paste into the via holes in the cell substrate, preparing back electrodes, and then drying;

4) preparing back surface fields, and then drying;

5) preparing front electrodes of the cell, and then drying;

6) plating an antireflection film on the upper surface of the cell substrate formed in step 4), so that the front electrodes are completely covered by the antireflection film; and

7) testing and sorting after sintering.

In the step 9), the antireflection film is a silicon nitride film. In the step 5), the front electrodes are prepared by screen printing technology. The first conductivity type is P-type.

A process for manufacturing a thin-film covered SE solar cell in an MWT structure, including the following steps:

1) selecting a silicon wafer of a first conductivity type, and forming a cell substrate with via holes by providing the via holes in predetermined positions of the silicon wafer, texturing, diffusing, performing via hole back junction protection and etching.

2) printing a mask on the surface of the cell substrate, and masking the regions to be re-doped under the electrodes;

3) etching the cell substrate with the mask, and removing any unnecessary PN junctions around the silicon wafer.

4) removing the PSG on the surface of the cell substrate, carrying out junction planing processing on the regions not masked by the paraffin mask, and removing the paraffin mask after the processing is completed;

5) filling paste into the via holes in the cell substrate, preparing back electrodes, and then drying;

6) preparing back surface fields, and then drying.

7) preparing front electrodes of the cell and then drying;

8) plating an antireflection film on the upper surface of the cell substrate formed in step 7), so that the front electrodes are covered completely by the antireflection film; and

9) testing and sorting after sintering.

As a further improvement in the process for manufacturing a thin-film covered SE solar cell in an MWT structure, the antireflection film is a silicon nitride film. The first conductivity type is P-type. The step 5) includes making the front electrodes of the cell by inkjet printing.

A thin-film covered MWT solar cell includes an antireflection film and front electrodes, the front electrodes being covered completely by the antireflection film on the front of the cell. The antireflection film is a silicon nitride film.

Beneficial effects: according to the present invention, when an MWT back contact solar cell is manufactured, the front electrodes are covered completely by the antireflection film, namely the front electrodes are directly in contact with the silicon wafer without penetration of the antireflection film, so as to reduce the series resistance, and improve the cell conversion efficiency. Meanwhile, the penetration depth when the front electrode silver paste is printed is also easier to control, so that the process is simplified. The front electrodes covered completely by the antireflection film are not directly in contact with the outside, so as to improve the corrosion resistance and oxidation resistance of the front electrodes.

### BRIEF DESCRIPTION OF THE DRAWINGS

FIG. 1 is a structural schematic diagram of a solar cell manufactured by a process for manufacturing a thin-film covered MWT solar cell according to the present invention.

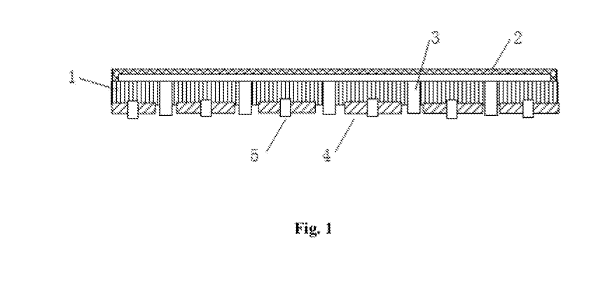

### DETAILED DESCRIPTION OF THE EMBODIMENTS

The present invention is further described below in conjunction with the accompanying drawings and specific embodiments. It should be understood that these embodiments are only used for illustrating the present invention, but the present invention is not limited thereto. Modifications in various equivalent forms made by those skilled in the art after reading the present invention should fall in the scope as defined by the appended claims of this application.

Embodiment 1: The present embodiment provides a process for manufacturing a thin-film covered MWT solar cell, which is completed through the following process steps:

1) Perforating: providing via holes 1 each with a diameter of 200-300 micrometers by using laser beams in predetermined positions on a selected P-type silicon wafer, the so-called predetermined positions being the positions where the front electrodes 3 of the solar cell are located, the number of the via holes being also the same as the number of the front electrodes 3.

2) Texturing: subjecting the silicon wafer to corrosion by using HF and HNO3, so as to form an egg structure 1-3 micrometers in size on the surface of the silicon wafer.

3) Diffusion: carrying out phosphorus diffusion on the silicon water at a high temperature by using phosphorus oxychloride and oxygen with a diffusion sheet resistance of 85 ohms, so as to form a PN junction.

4) Via hole back junction protection: printing a paraffin mask on the back of the via holes of the solar cell to protect each via hole and PN junction within 3 mm in diameter, so as to avoid destruction when etching is carried out.

5) Etching, paraffin mask removing and phosphorosilicate glass removing: removing any unnecessary N-type layers around the cell substrate 1 by etching, and removing the phosphorosilicate glass on the surface of the cell substrate 1.

6) Filling paste fully in the via holes in the cell substrate by screen printing, printing back electrodes 5, and then drying.

7) Printing back fields 4 by screen printing, and then drying.

8) Making front electrodes 3 by screen printing, and then drying.

9) Plating a silicon nitride film 2 on the front of the cell substrate 1, so that the front of the cell substrate 1 and the front electrodes 3 are completely covered by the thin silicon nitride film 2.

10) Sintering: forming an ohmic contact between each electrode and the cell substrate 1, and then testing and sorting, grading discriminatively according to electrical properties and packing for sale.

A thin-film covered MWT solar cell includes an antireflection film and front electrodes, the front electrodes being covered completely by the antireflection film on the front of the cell. The antireflection film is a silicon nitride film.

Embodiment 2: The present embodiment provides a process for manufacturing a thin-film covered SE solar cell in an MWT structure, including the following steps:

1) Perforating: providing via holes 1 each with a diameter of 200-300 micrometers by using laser beams in predetermined positions on a selected P-type silicon wafer, the so-called predetermined positions being the positions where the front electrodes 3 of the solar cell are located, the number of the via holes being also the same as the number of the front electrodes 3.

2) Texturing: subjecting the silicon wafer to corrosion by using HF and HNO3, so as to form an egg structure 1-3 micrometers in size on the surface of the silicon wafer.

3) Diffusion: carrying out phosphorus diffusion on the silicon wafer at a high temperature by using phosphorus oxychloride and oxygen with a diffusion sheet resistance of 85 ohms, so as to form a PN junction.

4) Via hole back junction protection: printing a paraffin mask on the back of the via holes of the solar cell to protect each via hole and PN junction within 3 mm in diameter; so as to avoid destruction when etching is carried out.

5) Printing the paraffin mask: inkjet, printing the paraffin mask on the upper surface of the cell substrate, the paraffin mask having the same pattern as the front grid fine pattern.

6) Etching, junction planing, paraffin mask removing and phosphorosilicate glass removing; etching off, by using an etching solution, a thin layer from the surface of the doped layer outside the mask to form a shallow diffusion layer, simultaneously removing any unnecessary parts around the cell substrate, and then washing the paraffin away and removing phosphorosilicate glass on the surface of the substrate 1.

7) Filling paste fully in the via holes in the cell substrate by screen printing, printing back electrodes 5, and then drying.

8) Printing back fields 4 by screen printing, and then drying.

9) Making front electrodes 3 by inkjet printing, and then drying.

10) Plating a silicon nitride film 2 on the front of the cell substrate 1, so that the front of the cell substrate 1 and the front electrodes 3 are completely covered by the thin silicon nitride film 2.

11) Sintering: forming an ohmic contact between each electrode and the cell substrate 1, and then testing and sorting, grading discriminatively according to electrical properties and packing for sale.

1. A process for manufacturing a thin-film covered MWT solar cell, comprising the following steps:
1) selecting a silicon wafer of a first conductivity type, and forming a cell substrate with via holes by providing the via holes in predetermined positions of the silicon wafer, texturing, diffusing, performing via hole back junction protection and etching;
2) removing PSG on the surface of the cell substrate;
3) filling paste into the via holes in the cell substrate, preparing back electrodes, and then drying;
4) preparing back surface fields, and then drying;
5) preparing front electrodes of the cell, and then drying;
6) plating an antireflection film on the upper surface of the cell substrate formed in step 4), so that the front electrodes are completely covered by the antireflection film; and
7) testing and sorting after sintering;

2. The process for manufacturing a thin-film covered MWT solar cell according to claim 1, wherein the antireflection film in the step 6) is a silicon nitride film.

3. The process for manufacturing a thin-film covered MWT solar cell according to claim 1, wherein in the step 5), the front electrodes are prepared by using screen printing technology.

4. A process for manufacturing a thin-film covered SE solar cell in an MWT structure, comprising the following steps:
1) selecting a silicon wafer of a first conductivity type, and forming a cell substrate with via holes by providing the via holes in predetermined positions of the silicon wafer, texturing, diffusing, performing via hole back junction protection and etching.
2) printing a mask on the surface of the cell substrate, and masking regions to be re-doped under electrodes;
3) etching the cell substrate with the mask, and removing any unnecessary PN junctions around the silicon wafer;
4) removing PSG on the surface of the cell substrate, carrying out junction planing processing on regions not masked by a paraffin mask, and removing the paraffin mask after the processing is completed;
5) filling paste into the via holes in the cell substrate, preparing back electrodes, and then drying;
6) preparing back surface fields, and then drying.
7) preparing front electrodes of the cell, and then drying;
8) plating an antireflection film on the upper surface of the cell substrate formed in step 7), so that the front electrodes are completely covered by the antireflection film; and
9) testing and sorting after sintering.

5. The process for manufacturing a thin-film covered MWT solar cell according to claim 4, wherein the antireflection film in the step 8) is a silicon nitride film.

6. The process for manufacturing a thin-film covered MWT solar cell according to claim 1, wherein the first conductivity type is P-type.

7. The process for manufacturing a thin-film covered MWT solar cell according to claim 4, wherein the step 7) comprises making the front electrodes of the cell by inkjet printing.

8. A thin-film covered MWT solar cell produced by the process for manufacturing a thin-film covered MWT solar cell according to claim 1, comprising an antireflection film and front electrodes, wherein the front electrodes are completely covered by the antireflection film of the cell.

9. The thin-film covered MWT solar cell according to claim 8, wherein the antireflection film is a silicon nitride film.

10. The process for manufacturing a thin-film covered MWT solar cell according to claim 4, wherein the first conductivity type is P-type.

11. A thin-film covered MWT solar cell produced by the process for manufacturing a thin-film covered MWT solar cell according to claim 2, comprising an antireflection film and front electrodes, wherein the front electrodes are completely covered by the antireflection film of the cell.

12. A thin-film covered MWT solar cell produced by the process for manufacturing a thin-film covered MWT solar cell according to claim 3, comprising an antireflection film and front electrodes, wherein the front electrodes are completely covered by the antireflection film of the cell.
